(19) United States
(12) Patent Application Publication
(10) Pub. No.: US 2015/0068585 A1
(43) Pub. Date: Mar. 12, 2015

(54) Capturing Reflected Solar EMR Energy

(71) Applicant: Edward Nathan Segal, Sunrise, FL (US)

(72) Inventor: Edward Nathan Segal, Sunrise, FL (US)

(21) Appl. No.: 14/484,067

(22) Filed: Sep. 11, 2014

Related U.S. Application Data
(60) Provisional application No. 61/876,609, filed on Sep. 11, 2013.

(51) Int. Cl. H01L 31/054; F24J 2/16

(52) U.S. Cl. CPC H01L 31/0547; F24J 2/16
USPC 136/246; 126/687

(57) ABSTRACT

Surfaces containing conversion elements may be positioned and shaped to concentrate or manipulate convergence of sunlight, for example, to produce a steady reflected beam within a wide range of concentration levels and to direct reflected beams for multiple reflections from solar power conversion mediums. The mediums can be positioned to avoid blocking reflected or other light so that unconverted energy may be directed to other surfaces and has several chances to be absorbed or converted. All of the devices may fit within the total converting surface area, e.g., within a concentrator's surface area. The method of solar power conversion may employ active and passive methods simultaneously and/or sequentially.

### CROSS-REFERENCE TO RELATED APPLICATIONS

This patent document claims benefit of the earlier filing date of U.S. provisional patent application No. 61/876,609, filed Sep. 11, 2013, which is hereby incorporated by reference in its entirety.

### BACKGROUND

Solar energy holds the promise of providing abundant and sustainable clean energy for modern societies, and many forms of solar power conversion systems have been developed to convert solar energy into other forms of energy that are more convenient for human use. Photovoltaic systems, for example, absorb sunlight in a process that converts energy from photons into voltage and current that electrical devices can use. Solar heating systems absorb the energy from sunlight to heat water or other materials that may be directly used for household purposes or may be used in a further energy conversion processes such as passive applications. For example, solar heating can boil water (or other liquids) to generate steam or gas pressure that drives a mechanical system such as a turbine and electrical generator. Current systems that convert solar energy for human use, however, can be expensive and inefficient. Accordingly, systems and methods for efficiently capturing or converting solar energy are desired.

### SUMMARY

In accordance with an aspect of the invention, this may be a method of manipulating light or sunlight into a steady or quasi steady beam of concentrated light. Such may be done whereas light which is affected by or that experiences a concentrator of some sort may be converging toward a focal point with some degree of precision depending on the concentrator and the light source and how they are positioned relative to each other. The light which is converging or concentrating could be manipulated or corrected through a method of convergence rate manipulation which might take place within a wide range of concentration levels. The steady beam may be passed on to a channel like pair of plates where once within, the steady beam of concentrated light could reflect back and forth multiple times within a wide range depending on the plate configuration and overall precision. The devices which may perform this manipulation could be considered as particular surfaces or surface areas which could be geometrically sized, shaped, and positioned relative to each other and the concentrator. Such surfaces may be covered with or constructed of solar power conversion devices which could receive the concentrated light of which some portion may reflect to some degree to another of the surface areas off of which some light may further reflect and so on. A wide variety of single or multiple power conversion devices may be applied including but not limited to photovoltaic cells known as solar cells, or material may reside behind the faces where such may include holes like pipes where some sort of fluid flows as in a thermal passive application.

One specific implementation is a system including a concentrator and corrective reflecting device including first and second corrective reflecting surfaces. The first corrective reflecting surface may be positioned to receive and reflect a beam from the concentrator while adjusting an aspect of a convergence rate of the beam. The second corrective reflecting device may be positioned to receive and reflect the beam from the first corrective reflecting surface, while correcting the uncorrected aspects of the convergence rate.

Another specific implementation is a solar energy conversion system including a first and a second collector. The first collector may be positioned to receive solar radiation on a first area of the first collector, and the second collector may be separated from the first collector to create a channel between the first collector and the second collector. Electromagnetic radiation reflected from the first area has a beam path within the channel, and the beam path includes multiple areas at which the beam path encounters one of the first and second collectors.

### BRIEF DESCRIPTION OF THE DRAWINGS

FIG. 1A shows a solar collector system according to an implementation employing parallel planar collectors to capture energy from multiple reflections or re-radiation of sunlight or other electromagnetic radiation.

FIG. 1B shows a cross-section of a solar collector system according to an implementation employing converging planar collectors to capture energy from multiple reflections or re-radiation of sunlight or other electromagnetic radiation.

FIG. 1C shows a cross-section of a solar collector system according to an implementation employing converging collectors and a curved feature to capture energy from multiple reflections or re-radiation of sunlight or other electromagnetic radiation.

FIGS. 2A and 2B respectively show a perspective view and a top view of a system in accordance with an implementation of the invention that confines light paths and reflective corrective surfaces behind and within the area of a rectangular lens.

FIG. 3A shows a front view of the devices situated under the lens and amongst the narrow side of the inverted pyramid shape of converging sunlight in the system of FIG. 2A.

FIG. 3B shows an enlarged section of a front view of the system of FIG. 2A.

FIG. 4 shows a side view of the devices situated under the lens and amongst the wider side of the converging light in the system of FIG. 2A.

FIG. 5 shows a work plane view of geometric figures for a lowermost edge of a second corrective reflective surface in the system of FIG. 2A.

FIG. 6 shows a work plane view of geometric figures for an uppermost edge of the second corrective reflective surface in the system of FIG. 2A.

FIG. 7 show a perspective view of a solar energy conversion system in accordance with an implementation that employs a single-surface corrective reflecting element to redirect and adjust the convergence rate of sunlight.

The drawings illustrate examples for the purpose of explanation and are not of the invention itself. Use of the same reference symbols in different figures indicates similar or identical items.

### DETAILED DESCRIPTION

A multi surface method of geometrically applying solar power conversion mediums about particularly shaped, sized, and situated locations within the converging portion of concentrating light where as the surfaces may serve to manipulate the convergence rates to result in a steady or collimated beam of concentrated light which may then be reflected multiple times in a controlled manner as to allow concentrated energy multiple chances to be converted into other forms of energy. Reflecting/absorbing surfaces can be arranged so that no light path is blocked or misdirected and so that all of the surfaces and other components may fit within the total area of a primary concentrator such as a lens. An overall single unit may be of most any size from microscopic to larger than a building, and multiple units may be efficiently arranged in an array that fully covers any desired area. The systems and method may be applied to most any conversion medium, not limited to photovoltaic cells (PVCs) or passive solar collection, and multiple mediums and may be configured for most any concentration or intensity level and wide range of possible reflections.

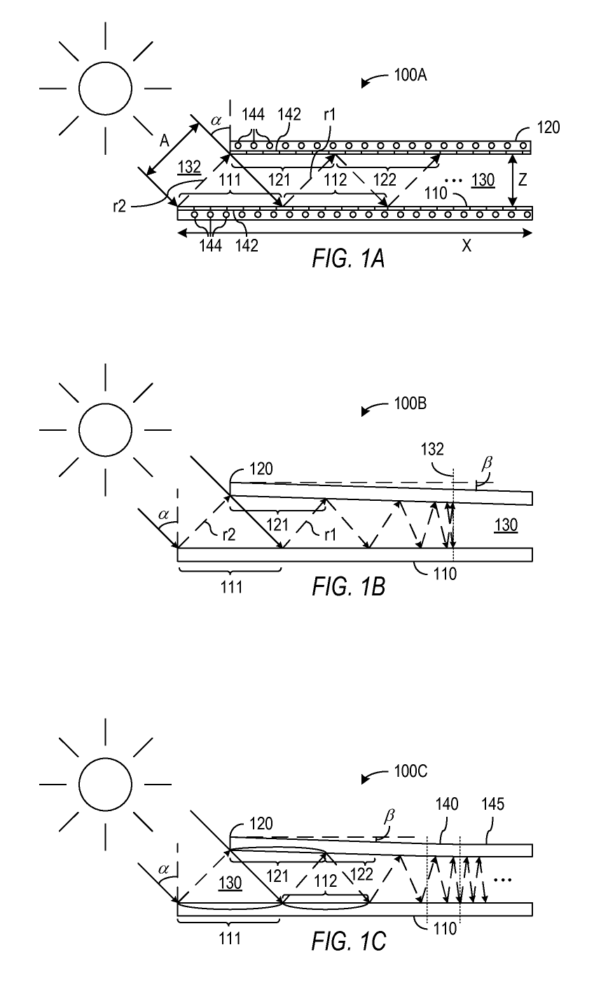

FIG. 1A shows a cross-section of a multi-reflection solar energy conversion device 100A. Device 100A includes a pair of collectors 110 and 120 that overlap and are separated to provide a light channel 130 between collectors 110. Collectors 110 and 120 may be substantially planar and may have any desired length X and any desired separation Z between collectors 110 and 120. Collectors 110 and 120 may similarly have any desired width perpendicular to length X and separation Z, and the width may depend on the desired power to be collected. An aperture 132 at one end of light channel 130 is exposed to sunlight at an angle α that may be related to the geometry of device 100A. (The term sunlight or light is used herein in a general sense to include any frequency of electromagnetic radiation and is not limited to electromagnetic radiation with frequencies in the visible spectrum.) In particular, collectors 110 and 120 may be positioned so that sunlight is incident on an area 111 of collector 110 at angle α. A solar tracking system (not shown) may be employed to change the orientation of collectors 110 and 120 or change the direction of incoming sunlight to achieve the desired incidence angle as the Earth rotates relative to the sun. Aperture 132 may have the same width as collectors 110 and 120 and a gap dimension A that depends on angle α, separation Z, and any offset of the sunward edges of collectors 110 and collector 120.

Area 111 on a surface of collector 110, which first receives sunlight, collects power from the incident sunlight and may, for example, include photovoltaic cells 142 or heat transfer elements 144. Photovoltaic cells 142 on collector 110 may be of any design that converts light into voltage or electrical current. Heat transfer elements 144 may include thermal mass to absorb light to heat a material and/or pipes, tubes, or a fluid jacket through which a fluid such as water flows within collector 110. In general, energy-conversion elements such as photovoltaic cells 142 or heat transfer elements 144 may be spread throughout collector 110, may cover the entire top surface of collector 110, or may be limited to specific areas of collector 110, e.g., limited to areas that receive sufficient electromagnetic radiation (EMR). For example, photovoltaic cells 142 may only be in areas close to aperture 132, but heat transfer elements may be distributed throughout collector 110. Multiple conversion methods may be applied simultaneously and/or sequentially on collector 110. Collector 110 may otherwise be made of any desired material with suitable load and heat bearing capabilities.

Regardless of the composition of collector 110, some sunlight incident on area 111 of collector 110 is not absorbed but may be reflected, scattered, or redirected in some fashion. FIG. 1A shows leading and trailing rays r1 and r2 of a beam corresponding to specular reflection from area 111. In conventional solar collectors, the reflected sunlight is lost. In device 100A, collector 120 is positioned so that the beam reflected from area 111 has a beam path incident on an area 121 of collector 120. As a result, collector 120 receives and may absorb light reflected from collector 110. All or a portion of the major surface of collector 120 that is nearest to collector 110 may include solar devices such as photovoltaic cells 142 or heat transfer elements 144, which may be the same or different from the solar devices on area 111 of collector 110. Alternatively, the surface of collector 120 facing toward collector 110 may be highly reflective. In either case, some light incident on area 121 of collector 120 may be reflected to an absorbing area 112 on collector 110, which may in turn reflect some light on to an area 122 of collector 120. Such reflections define a beam path between collectors 110 and 120 interacts with collectors multiple times, allowing multiple opportunities for energy to be captured and converted until the beam energy is insignificant. FIG. 1A shows several reflections of leading ray r2 on a beam path that could indefinitely (or to the end of channel 130.

A conventional solar energy conversion generally needs the sunward surface to be highly absorptive to provide high energy conversion efficiency. As a result, such solar systems may need to employ expensive anti-reflective coatings or suffer from loss of reflected energy. In contrast, collectors 110 and 120 can provide high efficiency collection without having low reflectance. For example, if surfaces of both collectors 110 and 120 have a reflectance about 10%, 10% of incident sunlight on area 111 may be reflected in a first reflection, but energy in reflected light at a third reflection from area 112 drops to less than about 0.1% of the incident energy. Accordingly, device 100A can achieve high collection efficiency even with structures having a significant reflectance.

Device 100A may also collect non-reflected radiation that might otherwise escape from collector 110 or 120. For example, collector 110 and 120 will typically be hotter than the surrounding environment when device 100A collects energy from sunlight, and the elevated temperature causes net radiation, e.g., blackbody radiation, from hot surfaces collectors 110 and 120. However, collectors 110 and 120 are positioned so that at least a fraction of the energy radiated from collector 110 or 120 may be collected by collector 110 or 120. Such collection may include direct capture of radiation traversing channel 130 and capture of radiation after one or more reflections.

Collectors 110 and 120 of the implementation of device 100A shown in FIG. 1A may be planar and parallel. With this configuration, the maximum number of reflections that device 100A can contain depends on the geometry of device 100A, e.g., on the separation Z between collectors 110 and 120, the lengths X of collectors 110 and 120, and the angle α of incidence of sunlight on collector 110. FIG. 1B shows a device 100B in which collectors 110 and 120 are at a non-zero angle β to each other and converge along the general direction that the reflected beam first travels within channel 130. With angle β smaller than angle α, the convergence of collectors 110 and 120 in device 100B causes successive reflections to be at smaller angles with collector 110 and also concentrates reflected beams into smaller areas. As shown in FIG. 1B, collectors 110 and 120 converge toward each other causing rays r1 and r2 respectively at the leading edge and the trailing edge of the beam reflected from area 111 of collector 110 to travel different distances down channel 130 before encountering collector 120. Since trailing beam r2 travels further than leading beam r1, the beam is compressed or concentrated along the length direction of channel 130. Device 100B may thus concentrate solar power that was not absorbed by a power conversion medium in any prior encounter with a collecting surface. The concentration may improved the ability of collectors 110 and 120 to re-capture electromagnetic radiation when compared to device 100A of FIG. 1A because beams reflected from absorbers are generally less intense than incident beams.

The decrease in the angle of reflected beams on the beam path in device 100B continues while the reflected beam generally heads inward (e.g., away from area 111) along channel 130 to a turning point 132, but the angle similarly increases when the path of the reflected beam begins heading back out of channel 130 (e.g., back toward area 111). For example, if angle α is about 40° and angle β is about 4°, a reflected beam headed inward along channel 130 may be reflected ten times from collector 120 before the beam passes through perpendicular to collector 110 and begins heading back toward aperture 132. In general, only a few reflections may be of interest because a high percentage of sunlight would typically be absorbed after two or three encounters with collecting surfaces

FIG. 1C shows a device 100C that is similar to device 100B but which further has one or more collecting areas 111, 112, . . . or 121, 122, . . . shaped to concentrate reflected light on a next collecting area. For example, on collector 110 of FIG. 1C, collecting area 111, which receives direct sunlight, may be shaped so that reflected light is concentrated on collecting area 121 of collector 120. For example, if area 111 is absorptive and only reflects 10% of incident light, area 111 may have a corrective reflecting surface shaped so that the reflected light is incident on an area of collector 120 that is one tenth the size of area 111. In the specific example, the reflected light incident on collector 120 will be as intense as the direct sunlight on area 111.

Area 111 of FIG. 1C can be shaped in a variety of ways to achieve the desired concentration. For example, area 111 may be curved in the same manner as a cylindrical or parabolic mirror that focuses light on the desired area 121. Alternatively, surface 111 may use a Fresnel-type configuration in which as set of flat sub-areas are at different angles chosen so that incident sunlight is focused on a small area of collector 120. Even though area 111 may be shaped to provide optical characteristics that adjust a convergence rate of sunlight, the same area 111 may contain solar energy conversion elements that absorb electromagnetic radiation in the conversion process but that inherently reflect some light because of conversion inefficiencies. The next encountered surface has the opportunity to capture and convert the energy in that reflected light.

Area 121 may also be shaped to concentrate light reflected from area 121 onto an area 112 of collector 110. The shape of area 121 in general depends on the convergence of light incident on area 121 and a desired convergence on the next area 112 on the beam path. Accordingly, the shape of area 121 may be selected to increase a convergence rate (e.g., concave), decrease the convergence rate (e.g., convex), or maintain the convergence rate (e.g., flat). Subsequent areas such as areas 112 and 122 on the beam path may also be shaped to have corrective reflecting surfaces.

One or both of collectors 110 and 120 may also be curved or otherwise shaped in a distal section 140 to transition to a section 145 of device 100C in which collectors 110 and 120 are parallel. In section 140 the angle between surfaces of collectors 110 and 120 decrease, e.g., from angle β at aperture 132 to zero. With the configuration of FIG. 1C, a large number of reflections along a beam path may be contained between a relatively small area 140 and 145 of collectors 110 and 120, so that light entering channel 130 is effectively trapped until collector 110 or 120 absorbs or converts the energy of the light. (Literal trapping of light may not feasible. A beam path, however, may be confined in channel 130 so that the beam path encounters collector 110 or 120 many times during which available electromagnetic radiation is almost completely absorbed or converted.)

One exemplary implementation of device 100C is a device in which collectors 110 and 120 are substantially planar and slightly angled toward each other for a measured length in order to reduce the reflective distance length of concentrated light energy directed to either collector 110 or 120. Where the reflections would otherwise become shortest before starting to return, e.g., in section 140, collectors 110 and 120 may be slightly curved back outward with the intention to trap the energy or to increase the number of times the concentrated energy may be passed back and forth within device 100C. The number of passes or reflections within channel 130 does not need to be infinite, and the number of passes needed to achieve a desired efficiency for device 100C can be determined from the reflectances or conversion efficiencies of collectors 110 and 120.

Device 100A of FIG. 1A and device 100B of FIG. 1B may have an advantage of being tolerant of a range of incidence angles α. Device 100C of FIG. 1C generally has a shape that may be tailored to the incident angle α of sunlight, the angular distribution of incident sunlight, and use of the solar energy. Accordingly, device 100C may particularly benefit from use with a solar tracker, although solar tracking may be similarly used with device 100A or 100B. The shapes of the corrective reflecting surface in area 111, for example, may also be tailored according to any optical elements (not shown) that control the convergence of sunlight incident on area 111.

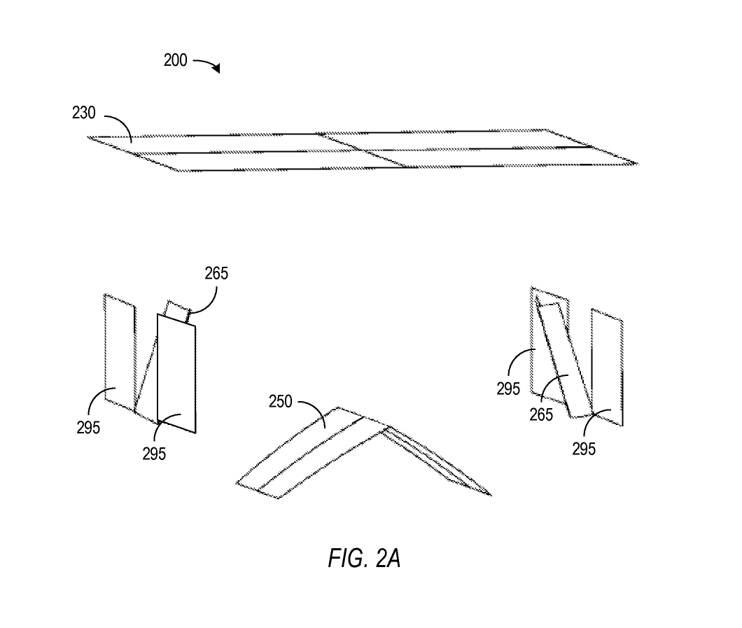

The implementations of devices 100A, 100B, and 100C described above collectors that may be horizontal and overlap, so that reflector 120 may block sunlight that would be otherwise incident on collector 110. In accordance with an alternative implementation, a multi-reflection collector uses two collecting surfaces that are upright so that neither collector blocks incident sunlight on the other. Optical turning systems can them be used to direct sunlight into a horizontal plane between collectors 110 and 120. FIG. 2A, for example, illustrates a solar energy conversion system 200 in which collectors and corrective reflecting surfaces are arranged to avoid blocking sunlight and maximize conversion of solar energy. System 200 includes a concentrator 230, a corrective reflecting device including two corrective reflecting elements 250 and 265, and a multi-reflection collecting system including four collecting surfaces or collector sections 295. The multi-reflection collecting system with collector sections 295 may employ the techniques and principles disclosed above for any of systems 100A, 100B, and 100C and collectors 110 and 120.

Operation of system 200 in the illustrated configuration positions concentrator 230 to receive sunlight that is directed along an optical axis of concentrator 230, and a sun tracking system (not shown) may be employed to maintain the desired orientation of concentrator 230 relative to the sun. Concentrator 230 causes collected sunlight to converge toward a focal point, and corrective reflective surface 250 may be sized and positioned to receive all of the collected sunlight before the sunlight reaches the focal point of concentrator 230. Corrective reflecting surface 250 acts to split the incident beam into two separate beams that are directed to the two opposite corrective reflecting surfaces 265. In particular, corrective reflecting surface 250 may have a ridge and sloped sides extending from the ridge, so that sunlight incident on one side of corrective reflecting surface 250 is directed to one corrective reflecting surface 265 and sunlight incident on the other side of corrective reflecting surface 250 is directed to the other corrective reflecting surface 265. The sides of corrective reflecting surface 250 may further be shaped, e.g., curved, to alter the convergence rate of the sunlight from concentrator 230. Each corrective reflecting surface 265 similarly splits the beam it receives from corrective reflecting surface 250 in two, so that four separate beams are respectively directed and the four collector sections 295. Each corrective reflecting surface 265 may also further adjust the convergence rate of the beams directed at collector sections 295.

Corrective reflecting surface 250 and corrective reflecting surfaces 265 collectively form a corrective reflecting device that effectively receives a vertically converging beam and produces four horizontal beams that may further follow beam paths including multiple reflections from a pair of collector sections 295. The corrective reflecting device can be designed to achieve a desired convergence, concentration, and direction for the four beams incident on collector sections 295, so that collector sections 295 can employ any of the techniques disclosed above with reference to FIGS. 1A to 1C. Further, corrective reflecting surfaces 250 and 265 may include conversion elements such as photovoltaic cells or passive solar energy conversion elements, so that in addition to the optical functions of surfaces 250 and 265, surfaces 250 and 265 may also directly participate in conversion of solar electromagnetic radiation to more convenient forms of energy. FIGS. 2B, 3A, 3B, 4, 5, and 6 illustrate in further details of one specific implementation of system 200 and illustrate how to determine shapes of elements that avoid blocking desired light paths or conversions.

In this implementation, the entire system 200 should track the sun so that the top of concentrator 230 remains approximately perpendicular to the direction of incident sunlight. Concentrator 230 may be a lens such as a Fresnel lens, and in the illustrated embodiment, concentrator 230 is a rectangular Fresnel lens. A rectangular lens receiving sunlight directed along an optical axis of the lens generally produces a beam in the shape of an inverted pyramid, where the light paths from any position once through the lens may converge to a common focal point on the optical axis of the lens. Dividing a rectangle area of concentrator 230 squarely in half one way and then again in half the other way may result in four rectangular areas or quadrants. As described further below, each quadrant in the logical division of concentrator 230 corresponds to a light beam that system 200 separates from light beams associated with the other quadrants. The light beam traveling through any quadrant of concentrator 230 begins converging toward the focal point of concentrator 230, and if unobstructed, the light will pass the focal point and diverge indefinitely or until something affects the beam.

In this implementation, the light may be manipulated within the converging area at a desired concentration level and may be redirected and altered in convergence rate to produce a steady or quasi steady beam of concentrated light before the beam reaches the focal point of concentrator 230. Such manipulations could affect individual or multiple aspects of the converging light simultaneously or sequentially where such manipulations might be performed by employing surface areas sized and shaped to achieve the desired effect. FIG. 2B shows a top view of system 200 illustrating how corrective reflecting surfaces 250 and 265 and collector sections 295 may all fit behind the area of concentrator 230. Lines are shown on concentrator 230 indicate four equal rectangular areas or quadrants that each may overlie an equal or similar section of system 200.

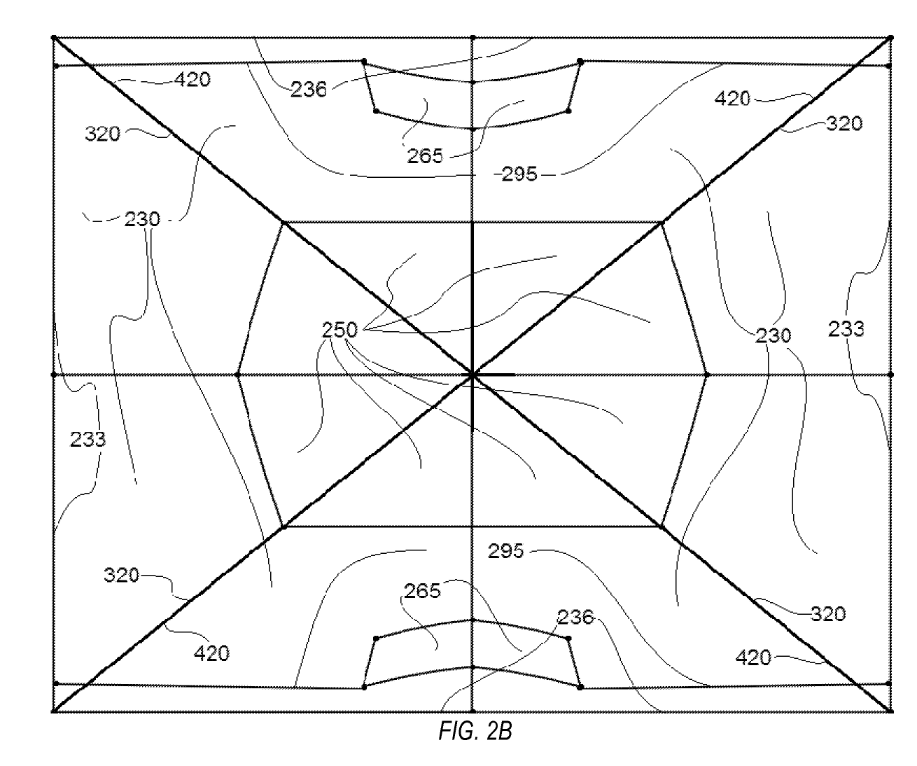

FIG. 3A shows a view of the devices in system 200 and some beam paths below a side 233, which could be a shorter side of the rectangular concentrator 230. Lines 320 in FIG. 3A represent the outermost portions (or edge or corner rays) of the converging light beam from concentrator 230, including a portion that would extend beyond where the beam interacts with surface 250. A desired initial concentration level may determine the location of the “First Contact Point” where the converging light could strike the first manipulation surface. This point may be along a centerline 300, which is the optical axis of concentrator 230, and before the focal point.

Most any desired concentration of incident sunlight may be achieved. A minimum level may be approximately a 4:1 ratio in the illustrated implementation. Example: if the focal length is 100 cm long and conversion surface (e.g., surface 250) is 50 cm from the focal point, where if a plane were put on the dividing point and parallel with the lens plane, the total light area may be ¼ (one quarter) the size of the lens and so the concentration level may be 4:1. If the remaining distance of 50 cm is halved again leaving 25 cm, the concentration level may now be 16:1. If the remaining 25 cm is halved again to 12.5 cm, the concentration level may be 64:1. So as may be determined, if the 12.5 cm length was halved to 6.25 cm yielding 256:1 and then halved again to 3.125 cm from the tip of a 100 cm focal length, this may result in 1024:1 concentrations which may require very high physical precision in positioning of elements. The actual resulting concentration levels from these calculations should turn out to be a bit higher as will be explained below. This example described below is for the specific case of a 4:1 concentration for ease of.

In this implementation, the views of FIGS. 3A and 3B show vertical centerline 300 extending a focal length of 100 c. In the exemplary configuration, devices relative to center line 300 have a mirror image opposite the line. Point A on center line 300 may be the first incidence point of light on surface 250, e.g., about 56 cm away from the focal point which should make point A 44 cm from concentrator 230. This placement selection, as many following, may require further adjustments as additional components are added to form a complete single unit or system 200. Reflecting angle α, which also may be adjusted later, is now about 61° relative to the center line 300 and may be employed to determine following calculations. Reflectors 310, which are portions of corrective reflecting elements 265, should be situated to remain beyond edge rays 320 as so they should not block any light. These reflectors 310 could determine the leading edge positions of the CRE-2 device pair, e.g., surfaces 265, which will be explained below. Each reflector 310 could be approximately but may not be exactly 45° relative to a portion 305 of surface 250 at angle α. A light path may be understood to travel from the center of the lens where the path could be centerline 300 which should strike portion 305 at point A and reflect off angle α where the reflection may follow path 301 and strike reflector 310 to reflect again and become path 302. Path 302 might appear in FIG. 3A as if heading toward opposite reflector 310 though only in this 2D view All just now explained should happen equally and opposite across centerline 300. The geometry which shows how reflections may be determined on this view and others to follow may be shown as a circle centered on the end point of a line. Whenever such a circle and line are seen together it may represent that the line is perpendicular to a reflector where beam path lines are tangent to opposite edges of the circle.

In this implementation, all the light between centerline 300 and outermost edge 320 may be reflected. As shown in FIG. 3A, edge path 320 may have converged with a path along centerline 300 at the focal point which is 56 cm from point A if path 300 had not experienced reflector portion 305 at angle α to become path 301. If edge path 320 was also reflected off portion 305 at angle α, it might still converge with 300 at 56 cm from point A though now in the direction of path 301, but arc 330 should be employed to replace reflector 305 as a corrective reflector which could manipulate the convergence rate and cause a quasi steady beam, from this view, of concentrated light. Arc 330 should be tangent to reflector 305 at point A so that path 301 might not be affected by this change. Path 320 however, could now reflect off arc 330 and become path 321. Geometry line 332 might end on the center point of arc 330 making it perpendicular to the reflecting angle at the point where edge path 320 meets arc 330. Path 321 may strike reflector 310 and so it may become path 322. In applying such a method, it may now be that all the light traveling between centerline 300 and edge path 320 is now traveling between paths 302 and 322.

As a result of this convergence rate manipulation in this implementation, it may be seen that the focal point is extended quite a bit in that paths 302 and 322 appear to be close to parallel with each other. This method may have adjusted the convergence rate while only of the narrow sides of the light as outlined in this front view. This need not be a perfect correction and over correction may be desirable in some applications. This could be done by changing the length of lines 331 and 332 which both come from the center of arc 330 representing its radius. Arc 330 could be applied to the curvature of the first strike component surface, e.g., corrective reflecting surface 250, which might be referred to as CRE-1 which may be acronym for “Corrective Reflecting Element One”. CRE-1 might be considered as one part of the entire overall system manipulation devices which cause converging light to become a steady beam of concentrated light which might be reflected multiple times in a controlled manner. CRE-1 may be considered as the first contact point surface device as it receives light before the other components.

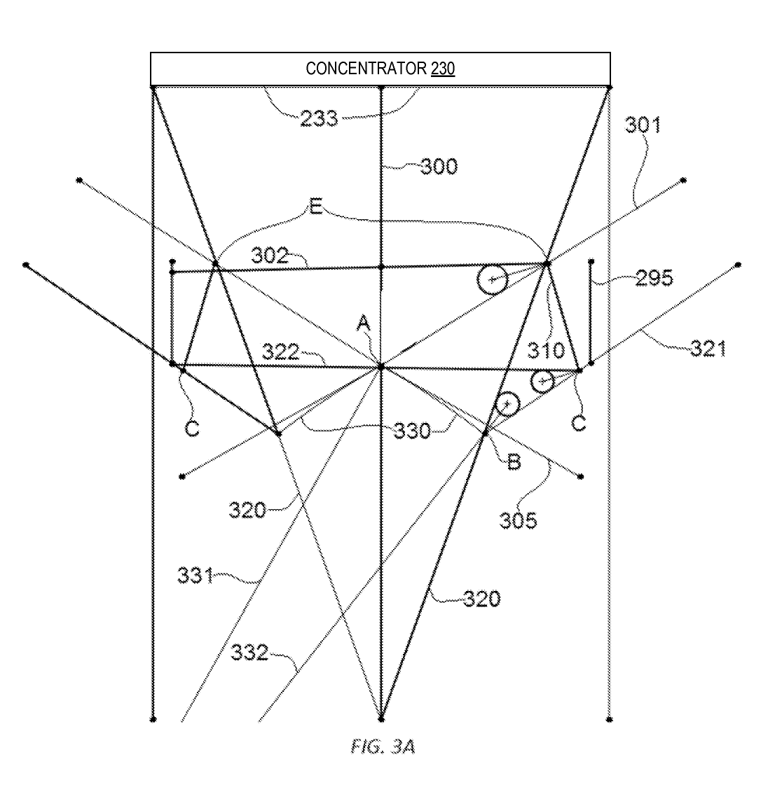

In this implementation, the length of CRE-1 may be determined from the wide side FIG. 4 where it could be that CRE-1 should reflect all of the light traveling from a side 236 of concentrator between center line 300 and edge ray 420 toward the focal point. It should be noted that outer edge 420 in this side view may also be considered as edge 320 in the front view in as much as centerline 300 may be the same line in the same position from either view where anything in reference to it should also be mirrored as an opposite across it. This could be to say that although no particular side was designated, if FIG. 4 is considered to be the “Right” side, then edge 420 on the left side of this drawing should be in the same position as edge 320 on the right side of FIG. 3 front view where this edge 320 may appear to be blocking it's opposite line which appears as if across 300 from a side view, which could have otherwise been viewable on the left side from a back view. This may further be to say that edges 320 and 420 represent the outermost paths of light originating from any outermost corner of the lens and so why they have both designations on the top lens view FIG. 2B. These designations might also be expressed in this way in as much as the wider side view convergence rate may require differing manipulations compared to the rate in which the narrow side is converging per the front view. Therefore they could now be referred to correctly as concerning the convergence aspect to which the intended reference is made. It should be understood that a resulting model below the lens 230 should appear to be symmetrical about centerline 300 which originated at the center point on the lens 230. Line 401 centered on centerline 300 at point A in the side view may be the uppermost apex edge of CRE-1. Line 421 could be a side apex of CRE-1 and derived from point B in this view which is the same point B where edge 320 meets arc 330 on each side of centerline 300 as shown in FIGS. 3A and B. Notice in FIG. 4 that CRE-1 should be long enough to receive all the light where outermost edge rays 420 might strike CRE-1. This may be to say that the sections of edge 420 between CRE-1 edges 401 and 421 may be considered as where CRE-1 can end as no further surface is needed beyond the light. The side apex should appear shorter than the upper apex as the lower portion might receive a slightly higher concentration of light relative to the upper portions as the light converges which is why the initial concentration level may be a bit higher than if a plane on point A received the light evenly. In some applications it may be desirable to overextend a surface to compensate for refraction through the lens or for other factors based on engineering decisions. In any case, as should now be understood, CRE-1 could be a particularly shaped and sized surface in a particular location relative to the lens. CRE-1 could also be considered four equal areas as light from each lens quadrant converges on two different sides of CRE-1, each going at a downward and inward angle toward the focal point and so it may be understood that the purpose of CRE-1 is to manipulate the shorter side of each quadrant.

FIG. 3B shows path 322 as appearing to strike a bit below point A. As such it may look like CRE-1 will block part of the light. The paths in this view resulted from reflection angles in this view which, though they may be true as per this 2D drawing, the actual true paths could be a bit different as they are influenced by surfaces having additional angles not shown in this view. Reflectors 310 could represent only the leading edges of the CRE-2 devices which might be placed in these positions. CRE-2 may consist of angles and curvatures which affect light paths. In this implementation the CRE-2 angles and curvatures may be found separately for each the uppermost and the lowermost portions of the CRE-2. Each set of calculations may be done on a plane which may be derived from perpendicular lines found on other planes as will be explained. It may be desirable to determine the lowermost edge of CRE-2 first as this will typically be a bit wider than the uppermost edge.

In this implementation, a pair of CRE-2 devices could be employed to correct the wide sides of light which may otherwise converge at the original focal point. More specifically though, each of the two CRE-2 devices may have two surface sections where each of the four surface sections could correct the longer side of one quadrant of the converging light. The top view of FIG. 2B may show the relative positions of each CRE-2 as each corrective reflecting surface 265 across from CRE-1 as corrective reflecting surface 250. The face areas may appear a bit less skewed in the side view of FIG. 4 where it appears as one CRE-2 as it is blocking the other. Reflectors 310 could be the leading edge positions as viewed in FIGS. 3A and 3B and so the position of reflectors 310 should show the precise location of each CRE-2 relative to the other components. Each CRE-2 may be similar in many ways to the CRE-1 device though a bit more complex for a few reasons which might be explained in the following. CRE-1 should have split the light into two directions moving between paths 301 and 321 on each side of centerline 300 in FIG. 3A. Each CRE-2 may also perform a similar operation on a wide side of light, both of which have not been corrected.

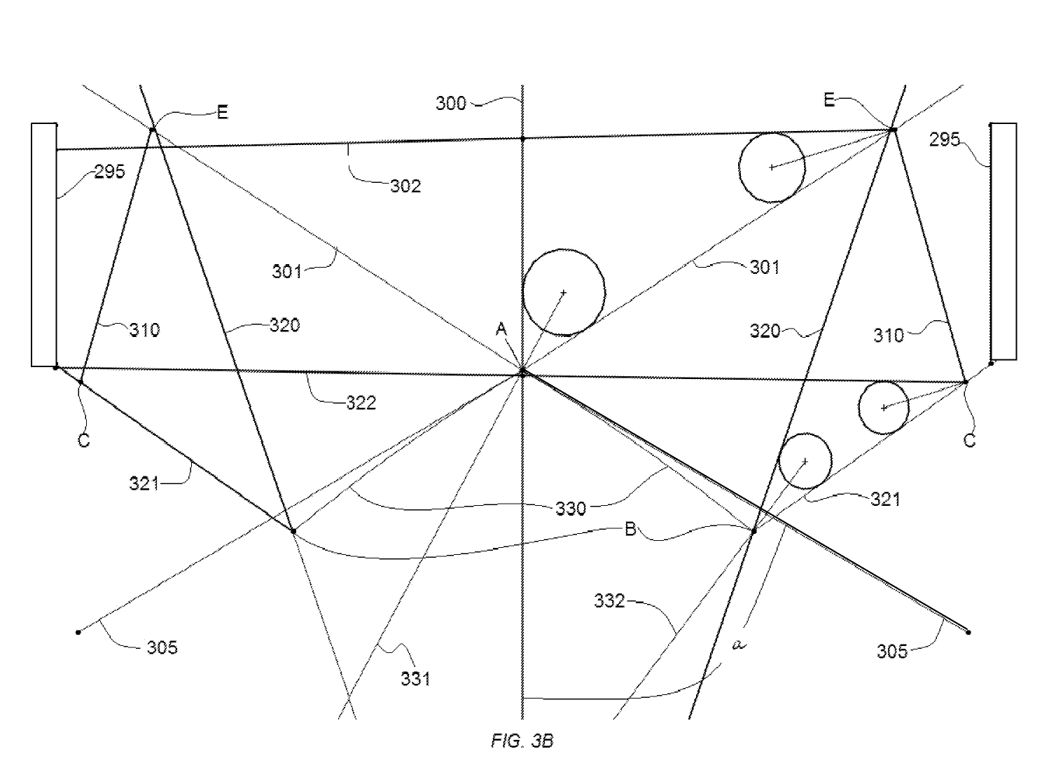

In this implementation, the lowermost edge of a CRE-2 should be an arc at an angle from the lower end point of reflector 310 which could be the leading edge of the CRE-2 in FIG. 3B. If viewing the arc from FIG. 4, it should appear to begin on 300 and extend outward. FIG. 5 could be the work plane for finding this arc and should be derived from path 321 in the front view FIG. 3A and perpendicular CRE-1 edge 421 in FIG. 4. Path 321 in FIG. 5 should be the same line at the same length as in FIG. 3A, which is the same length as the portion of outermost path 320 from arc 330 point B to the focal point. Point B is the same point in FIG. 5, FIGS. 3 A and 3B, and FIG. 4 in which it is the midpoint of CRE-1 edge 421. Edge 421 in FIG. 5 could be half of a side apex of CRE-1 as from point B to an end in FIG. 4. Line 521 may connect the ends of edge 421 to path 321 making a right triangle in FIG. 5. The length of 521 should be the same as edge 420 from CRE-1 side apex 421 to the focal point in FIG. 4. Edge 420 should be the outermost path of the wide side of the light and is now represented as 521 in FIG. 5. The distance length from point B to point C along path 321 where it meets arc 530 in FIG. 5 may be the same length as path 321 from arc 330 to where it intersects reflector 310 in FIGS. 3A and 3B. Distance 550 may be the clearance distance between the lower most points of each leading edge which may be seen in FIGS. 3A and B front view as the distance between the 2 mirrored points C. In the top view of FIG. 2B, the vertical line path from the center to each CRE-2 leading edge should be reflected across toward its opposite though where it will clear the other CRE-2, i.e., corrective reflecting surface 265 and instead strike a collector section 295 which will be explained below. The length of vertical line 541 in FIG. 5 should be the same length as vertical line 540 which should be the vertical distance length from point C to path 521 which may be considered the presumed width of CRE-2 so it may receive all the light between paths 321 and 521 at this position. Lines 421, 540, and 541 should all be parallel. Line 504 intersects line 541 at midpoint and as such, a reflector which is perpendicular to line 504 may reflect path 321 to the lower end point of line 541 which would clear the other CRE-2 however the clearance may not need to be this great because line 541 may be the total length from which the arc is derived while the resulting arc clearance distance may be a bit less and so a more accurate method may employ a clearance offset adjustment angle for fine tuning. This angle may be the angle between line 504 and line 570. Line 570 should be perpendicular to 505 which may be tangent to arc 530 at point C. Path 321 may reflect off arc 530 to become path 580. Lines 570 and 575 could be the radius length of arc 530 as they should meet at a point beyond the edge of this drawing. As such, line 575 should be perpendicular to line 530 at the point where ray 521 could reflect as ray 590. And so it may be that the location, angle, and radius of arc 530 which could be a lowermost edge of CRE-2, are all correct.

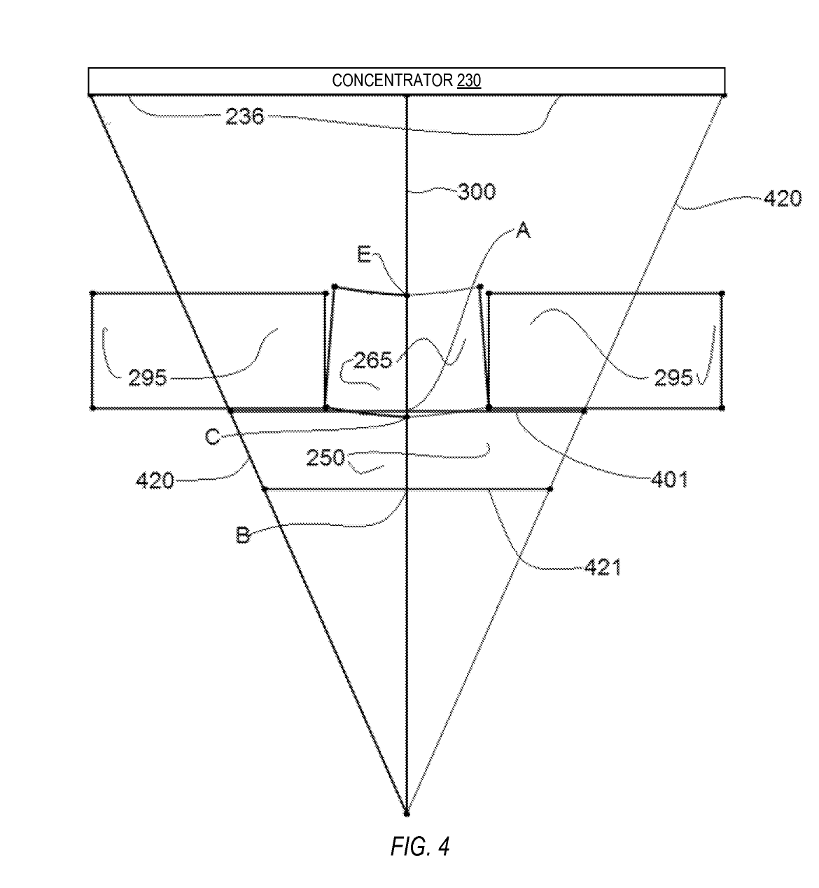

In this implementation the uppermost edge of a CRE-2 may be an arc at an angle starting at the upper end point of reflector 310 which could be the leading edge of the CRE-2 in FIG. 3B. If viewing the arc from FIG. 4, it should appear to begin on centerline 300 and extend outward. FIG. 6 could be the work plane for finding this arc and should be derived from path 301 in the front view FIG. 3A and perpendicular CRE-1 edge 401 in FIG. 4. Path 301 in FIG. 6 should be the same line at the same length as in FIG. 3A, which is the same length as the portion of centerline path 300 from arc 330 point A to the focal point. Point A is the same point in FIG. 6, FIGS. 3 A and B, and FIG. 4 in which it is midpoint CRE-1 edge 401. Edge 401 in FIG. 6 could be half of a top apex of CRE-1 as from point A to an end in FIG. 4. Line 601 may connect the ends of CRE-1 edge 401 to path 301 making a right triangle in FIG. 6. The length of 601 should be the same as edge ray 420 from CRE-1 top apex 401 to the focal point in FIG. 4. Edge ray 420 should be the outermost path of the wide side of the light beam and is now represented as ray 601 in FIG. 6. The distance length from point A to E along path 301 where it meets arc 630 in FIG. 6 may be the same length as path 301 from arc 330 to where it intersects reflector 310 in FIGS. 3A and B. Distance 650 may be the clearance distance between the upper most points of each leading edge which may be seen in FIGS. 3A and B as the distance between the two mirrored points E. In the top view of FIG. 2B, it should be understood that the vertical line path from the center to each CRE-2 leading edge should be reflected across toward its opposite though where it will clear the other CRE-2 as corrective reflecting surface 265 and instead strike a collector section 295 which will be explained below. The length of vertical line 641 in FIG. 6 should be the same length as vertical line 640 which should be the vertical distance length from point E to path 601 which may be considered the presumed width of CRE-2 so it may receive all the light between path 301 and 601 at this position. Lines 401, 640, and 641 should all be parallel. Line 604 meets the midpoint of line 641. A reflector if at point A and perpendicular to line 604 could reflect path 301 to the lower end point of line 641 which would clear the other CRE-2 however the clearance may not need to be this great because line 641 may be the total length from which the arc is derived while the arc clearance distance may be a bit less and so a more accurate method may employ a clearance offset adjustment angle for fine tuning. This angle may be the angle between line 604 and line 670. Line 670 should be perpendicular to line 605 which may be tangent to arc 630 at point E. Path 301 may reflect off arc 630 to become path 680. Lines 670 and 675 could be the radius length of arc 630 as they should meet at a point beyond the edge of this drawing. As such, line 675 should be perpendicular to line 630 at the point where ray 601 could reflect to become ray 690. And so it may be that the location, angle, and radius of arc 630 which could be an uppermost edge of CRE-2, may be correct.

Now that both the lowermost and the uppermost edges of a CRE-2 surface may have been found, they may be joined together with a straight ridged material which may represent the leading edge line in its position reflectors 310 in FIG. 3B in this implementation in which another straight ridged material may be constructed as to join the outermost ends of the upper and lower edges together. If applied in this way, the line may represent the outmost edge of the surface of CRE-2 and so, it may appear as a complete outline of a CRE-2 surface. An actual surface may be created by rolling a semi-ridged sheet like material starting on the straight ridged leading edge and rolling it outward until the outermost surface edge is covered. Semi-ridged sheet like material may be similar to thin metal which may roll somewhat in most any direction but only in one direction at a time in that it may become ridged like as if a sheet of paper is rolled into a tube. The recent actions as described above may result in the creation of one surface of one CRE-2 devices. A mirror of this surface may be constructed similarly but opposite across the leading edge line position as per 300 in FIG. 4 which may form one complete CRE-2 device however two may be needed in this implementation. A mirror of the complete device may be similarly constructed and may be situated mirror like across centerline 300 in FIG. 3B where the correct position of the leading edge reflectors 310 may be found.

The wide side of the converging light in this implementation may now have been corrected similarly as how CRE-1 may have corrected the narrow side of the converging light. Notice line 580 in FIG. 5 and line 680 in FIG. 6 may not appear to clear edge 541 or 641, respectively, which may represent the outermost edge of the opposite side CRE-2 where as such it may block some of the light however, this 2D representation may once again by incorrect as these reflections experience multiple angles about the CRE-2 and so the actual paths may only be determined after the entire CRE-2 surface is figured. The results of such manipulation of the wide side of the converging light may be paths 580 and 590 per the lowermost and outermost corners of one CRE-2 surface area which might correct the uncorrected side light which may have originated from one equal corner quadrant section of the lens in FIG. 2B in this implementation. Similarly, path lines 680 and 690 may be the reflected path lines from the uppermost corners of the one CRE-2 surface. These four lines may all be close to parallel with each other so as that the converging light which now may never reach any focal point may have become a steady or quasi steady beam of concentrated light of which paths 580, 590, 680, and 690 represents each outermost edge of the light from any one quadrant of the lens in FIG. 2B after being manipulated by the CRE set of precisely sized and situated curvatures. While these 2D calculations may have resulted in these possible light paths, as explained they may not be precisely correct however, it may be possible to adjust the dimensions further.

One anomaly which may also be considered in regards to surface size area for the outermost edge of CRE-2 is, although it may be perceived that lines 580, 590, 680, and 690 each represent the outermost corner where it may be presumed that all the light is now encompassed within them, this might not be entirely true because of the curvature of CRE-1 in relation to its distance to CRE-2 which may cause a small section of an outermost edge of light to be a bit wider than as the construction of the CRE-2 outermost edge was described. This could be a relatively simple problem to solve by over extending the surface a small amount. Alternatively, it may be possible to geometrically figure a more precise solution which may be similar as figuring which area of the outermost length edge of the radius of CRE-1 is closest to the outermost edge of CRE-2 if each first received and angular adjustment to compensate for the multiple angle along with the convex curvature offset which may have caused this slight overextension anomaly.

In this implementation, the true resulting theoretical light path may now be found from most any point behind any lens quadrant as seen in the top view of FIG. 2B, which should be a straight line from such a point to the focal point. Through meticulous geometrical calculations it may be possible to determine the point on CRE-1 at which this path would strike and as such, it may be possible to calculate the true reflection angle from that point which should be toward the CRE-2 on the same side of the CRE-1 which the light is reflected from and this may also be the CRE-2 section surface which can be seen within the same lens quadrant in FIG. 2B as from which the light path originated. It may then be possible to calculate the point on the CRE-2 device which the light path now strikes and so it may be possible to determine the actual reflecting path which should proceed across toward the collector surface. This same course of events may also be applied to any other point behind any other of the lens quadrants.

Each collector section 295 is for the most part in the illustrated implementation has a flat surface which may be made of a solar power conversion device or may be covered with such as like all the other surface shapes above. Any surface material could have reflective qualities and so therefore it may be possible to determine a true reflection angle once the approach angle is known. Such a path may be adjusted so that it will strike the opposite collector section 295 where this path may be reflected back and forth between a pair of collector sections. As seen in FIG. 2B, there are four collector sections 295 where it may be that they are configured as two pairs which rest across from one another. Such collector surface sections may appear to be close to parallel with each other as across each shorter half of the lens in the top view of FIG. 2B or on the same side of centerline 300 in the side view of FIG. 4 where each shown collector section 295 appears to be blocking its pair. A pair could be configured so that light may reflect across several times. Each collector section in a pair may be angled slightly toward each other in order to shorten the distance between each reflection of light which could have first struck a collector section at the angle caused by lengths 550 and 541 in FIG. 5 and lengths 650 and 641 in FIG. 6 which could be considered CRE-2 clearance distance and widths. Each collector section may also be curved back outwards at some point to increase possible reflections.

In this implementation most any of the mentioned components may be constructed with most any ridged material where each specific design intention may have different needs based on engineering decisions. As should now be understood, the CRE (Corrective Reflective Element) set devices may perform together in array sets where each surface section will typically correct and reflect one quadrant or ¼ of the converging pyramid in the implementation of FIG. 2A. The CRE and collector devices might all for the most part be nothing more than a surface of which its particular position, size, and shape are relative to each other and other components. In review, the CRE devices may divide, correct and reflect different aspects of converging light to form steady beams of concentrated light which may then be reflected several times in a controlled and somewhat predicable manner. Collector surface pairs may be considered the final stage of these multiple reflections.

In this implementation each of the surfaces may be made of or covered with a solar power conversion device or material behind any surface may be employed as a fluid jacket with tubes or channels to pass a fluid for a thermal transfer passive system. Accordingly, a method of shaping and positioning the conversion mediums is provided. Decisions regarding each of the above mentioned parameters may be engineered for each and every different array type depending on its intended application. These adjustment parameters may include but may not be limited to parameters such as: overall size and thickness, size of each concentrator, focal point length, initial concentration level, the number of desired possible reflections, type of conversion material to be used or applied, and several other factors.

The top lens or concentrator may be of most any type from clear plastic or treated glass or could be a thin lightweight Fresnel lens of most any size and configuration although it may be best for it to be in somewhat even proportions such as the rectangular lens in the implementation of FIG. 2A though this is also dependent on several engineering decisions per intended application.

System 200 of FIG. 2A employs a corrective reflective device that employs multiple corrective reflective elements or surfaces 250 and 265 to redirect and alter the convergence of solar light from concentrator 230 for introduction to multiple reflection system formed by collector sections 295. The two element configuration may have in a benefit that each surface 250 or 265 only needs to be curved in one direction to collectively alter convergence rates in two directions. Surfaces 250 may thus be simpler or less expensive to manufacture, using sheet material as described above.

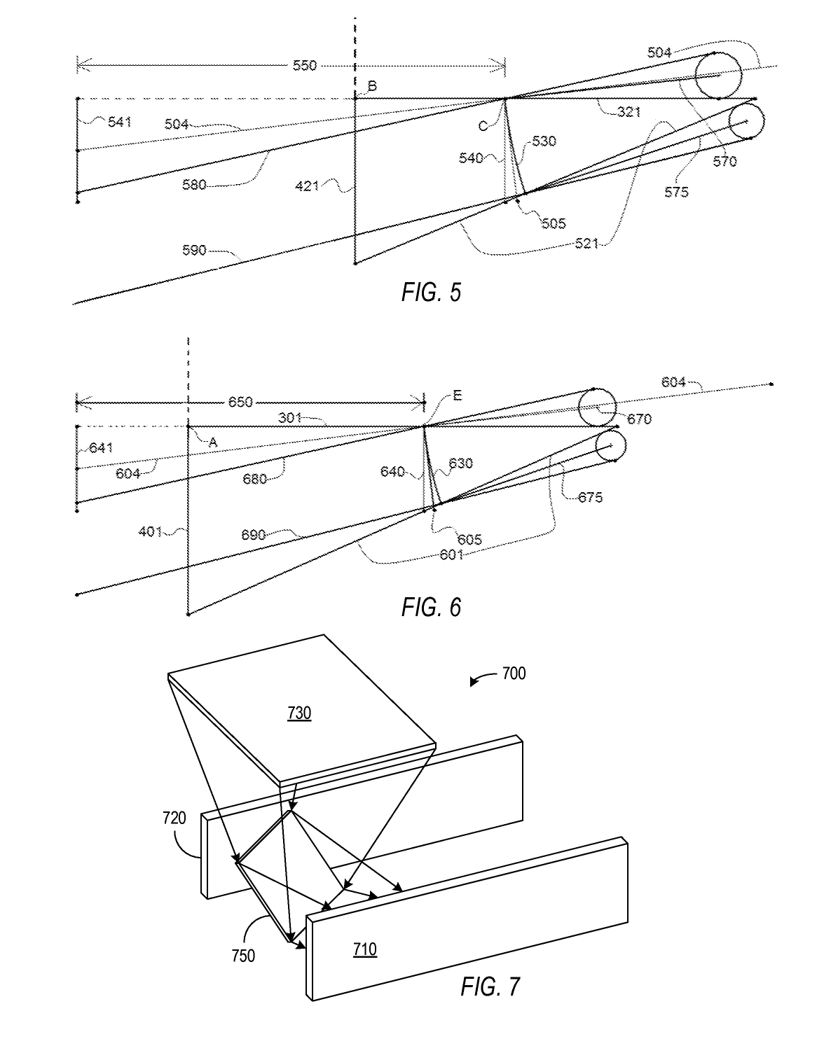

A corrective reflective device may alternatively employ more or fewer surfaces for redirecting and altering the convergence of solar light. FIG. 7, for example, illustrates a system 700 that includes upright collector sections 710 and 720 that may act as a multi-reflection collector such as described above with reference to FIGS. 1A, 1B, and 1C. System 700 further includes a concentrator 730, which may be a rectangular Fresnel lens, that directs a converging beam at a single-surface corrective reflecting device 750. Device 750 may be angled so that a central ray along the optical axis of concentrator 730 is reflected from being vertical to being horizontal and at a desired angle relative to collector section 710 to provide a horizontal beam path with multiple reflections from collector sections 710 and 712. Device 750 may be further shaped to alter the convergence rate of the sunlight, e.g., to create a collimated beam of concentrated electromagnetic radiation. As with the above implementations, system 700 may include any desired type or types of solar energy converting elements on any surface of corrective reflecting device 750 and collector sections 710 and 720.

A framework or mounting structure of some sort may aid in maintaining the geometric relations between the components as explained above and may also be dependent on engineering decisions. Such a framework may integrate system 200 or 700 into a modular unit that may be assembled or tiled with other similar units to create a solar array covering any desired area.

A solar power conversion device may have surfaces selected according to a method which may be incorporated with existing of future conversion devices which could be applied to cover or become the surface areas situated in relation to one another and the concentrator which may allow some increase in the overall conversion efficiency. It may be possible to employ multiple conversion techniques sequentially and or simultaneously.

Different geometry or size relationships of the systems described herein may be more effective for different applications. For example, where a small scale size in relation to the amount of light energy being concentrated may be more intended for the boiler heat transfer passive water jacket effect at a higher concentration of sunlight, such a high concentration may be too strong for Solar Cells to be applied. Other configurations may be more suitable for PVC coated faces and could also be for mild fluid heating or even both at the same time.

One practical operation of this set of devices is to re-align concentrated or highly concentrated sunlight energy so that the electromagnetic radiation may strike a passive boiler or conversion device and where the un-absorbed energy may be re-radiated in a controlled manner as to strike the same device multiple times instead of dissipating after only one (1) pass as is done in most ordinary solar power conversion systems. This more efficient method of contact with natural sunlight energy on to a radiator (water jacket) boiler or PVC coated device may significantly increase the amount of transferred electromagnetic radiation thus making it practical as well as economical to use this abundant energy source. Prior solar power conversion system, no matter what method of transfer or overall function and form, may be limited in the amount of realized energy and thus have a similar efficiency as one another because each of those differing systems might have only one (1) chance to absorb or convert the available directed sunlight energy where after that one pass, all of the un-absorbed energy is directed back out and away from the power transfer system and is effectively lost. Some of the systems and methods discloses herein overcome this common limitation of prior solar conversion systems.

Although particular implementations have been disclosed, these implementations are only examples and should not be taken as limitations. Various adaptations and combinations of features of the implementations disclosed are within the scope of the following claims.

What is claimed is:

1. A system comprising:
a concentrator;
a first corrective reflecting element positioned to receive and reflect a beam from the concentrator while adjusting an aspect of a convergence rate of the beam; and
a second corrective reflecting element positioned to receive and reflect the beam from the first corrective reflecting element positioned to receive and reflect a beam from the concentrator while adjusting an aspect of a while correcting the uncorrected aspects of the convergence rate.

2. The system of claim 1, further comprising a multiple reflection system positioned to receive the beam from the second corrective reflecting element, and reflect such the beam multiple times between two surface areas of the multiple reflection system.

3. The system of claim 2, wherein the two parallel surfaces are off parallel causing subsequent reflections to overlap and become shorter as the beam travels between the two surfaces.

4. The system of claim 3, wherein the two off parallel plates are curved outward at a point before overlapping reflections reverse a direction of travel between the two plates.

5. The system of claim 4, further comprising solar power conversion devices, wherein the solar power conversion devices are mounted on one or more of the two surfaces of the multiple reflection system and the first and second corrective reflecting.

6. The system of claim 5, wherein the multiple reflection system, the first and second corrective reflecting elements, and the solar power conversion devices fit under and within a sunlight receiving surface area or the concentrator area to form a unit so as not to interfere with another adjacent unit where multiple units are tiled to form an array.

7. A solar energy conversion system comprising:
a first collector positioned to receive solar radiation on a first area of the first collector; and
a second collector separated from the first collector to create a channel between the first collector and the second collector, wherein:
electromagnetic radiation reflected from the first area has a beam path within the channel; and
the beam path includes multiple areas at which the beam path encounters one of the first and second collectors.

8. The system of claim 7, wherein the first area of the first collector is shaped to alter a rate of convergence of the solar radiation.

9. The system of claim 7, wherein the second collector converges toward the first collector along a direction of the beam path.

10. The system of claim 9, wherein convergence of the first collector and the second collector concentrates the beam path.

11. The system of claim 9, wherein a portion of at least one of the first collector and the second collector is curved in a manner that confines multiple reflections of the beam path with a region of the channel.

12. The system of claim 7, further comprising a corrective reflecting device positioned to direct the solar radiation onto the first area of the first collector, wherein the corrective reflecting element changes a direction and a convergence of the solar radiation directed onto the first area.
